(19) United States
(12) Patent Application Publication
(10) Pub. No.: US 2006/0285417 A1
(43) Pub. Date: Dec. 21, 2006

(54) TRANSFORMER COUPLED CLOCK INTERFACE CIRCUIT FOR MEMORY MODULES

(75) Inventors: Robert D. Washburn, Malibu, CA (US); Robert F. McClanahan, Valencia, CA (US)

Correspondence Address: BROWN RAYSMAN MILLSTEIN FELDER & STEINER, LLP, 1880 CENTURY PARK EAST, 12TH FLOOR, LOS ANGELES, CA, 90067, US

(73) Assignee: THUNDER CREATIVE TECHNOLOGIES, INC., Malibu, CA (US)

(21) Appl. No.: 11/420,214

(22) Filed: May 24, 2006

Related U.S. Application Data
(60) Provisional application No. 60/684,878, filed on May 25, 2005.

(51) Int. Cl. G11C 5/14

(52) U.S. Cl. 365/226

(57) ABSTRACT

The invention is a clock interface circuit for high-speed computer memory modules. It provides improved timing margin due to improved rise and fall times than achieved with present JEDEC specified clock distribution and timing networks. The invention also provides for improved clock and inverse clock symmetry around VREF.

### CROSS-REFERENCE TO RELATED APPLICATIONS

This patent application claims priority to provisional patent application 60/684,878 filed on May 25, 2005 and incorporated by reference herein in its entirety.

### COPYRIGHT NOTICE

A portion of the disclosure of this patent document contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### FIELD OF THE INVENTION

The invention relates to the field of computer memory modules.

### BACKGROUND

Many high-speed computer memory modules, such as the double data rate, SDRAM, dual inline memory modules common to most present personal computers and network servers, use a clock interface such as illustrated in FIG. 1. A differential input clock signal 110A and 10B is coupled to a matched 120-ohm termination resistor 112. The clock signals are then coupled to individual memory devices over matched impedance (60 to 65 ohms) transmission lines 113A-113C. Up to six memory devices (two from each branch 113A-113C in FIG. 1) may be driven directly from each clock input with a 1.5 pf capacitor (e.g. capacitor 114) used to terminate a network output when the output is not applied to a memory device input.

Precise control of the lengths of the segments of the transmission lines controls memory module clock (and control signal) timing. The characteristic impedance of the transmission line clock distribution network limits signal rise and fall times and thus limits realizable clock operating frequencies.

### SUMMARY

The invention is a high-speed clock interface circuit. In one embodiment, the invention is used in connection with computer main memory and memory modules. The invention incorporates a step-down transformer that allows distribution of a clock over lower characteristic impedance transmission lines. As a result, clock rise and fall times and timing margin are improved. The invention includes a matched termination resistor for the differential clock input to the module, means for blocking DC currents from both the primary and secondary transformer windings, means for resetting the transformer, means for both referencing the clock to the VREF input to the memory device and ensuring symmetric operation of the clock around the reference voltage, and means for insuring a DC offset voltage between clock and clock inverse inputs to the memory device when the clock is not present.

Other features and advantages will become apparent from the following detailed description, taken in conjunction with the accompanying drawings, which illustrate by way of example, the features of the various embodiments.

### BRIEF DESCRIPTION OF THE DRAWING

FIG. 1 is an example of a prior art clock distribution scheme.

FIG. 2 is block diagram of one embodiment of the invention.

FIG. 3 is a circuit diagram of an embodiment of the invention.

### DETAILED DESCRIPTION

The invention is a high speed, transformer coupled clock interface circuit. In one embodiment it is used for coupling differential clock signals from the input connector of a memory module to the appropriate pins of one or more memory devices on the memory module. In the following description, numerous specific details are set forth to provide a more thorough description of embodiments of the invention. It is apparent, however, to one skilled in the art, that the invention may be practiced without these specific details. In other instances, well known features have not been described in detail so as not to obscure the invention.

Discussion of the invention is directed in one example embodiment toward application to 184-pin, 2.5 Volt (VDD)/2.5 Volt (VDDQ), Unbuffered, Non-ECC, Double Data Rate, Synchronous DRAM Dual In-Line Memory Modules (DDR SDRAM DIMMs), henceforth referred to as DIMMs. DIMMs are intended for use as main memory when installed in PCs and network servers. While the present discussion is directed toward 184-pin DIMM modules, the invention is not so limited and can be applicable to a wide variety of modular and non-modular memory configurations as well as many non-memory device interfaces.

Although achievement of high-speed memory module operation depends on many factors, a clean clock with responsive rise and fall times and controlled distribution times is an important element. Typical 184-pin DIMM modules have 3 differential clock inputs.

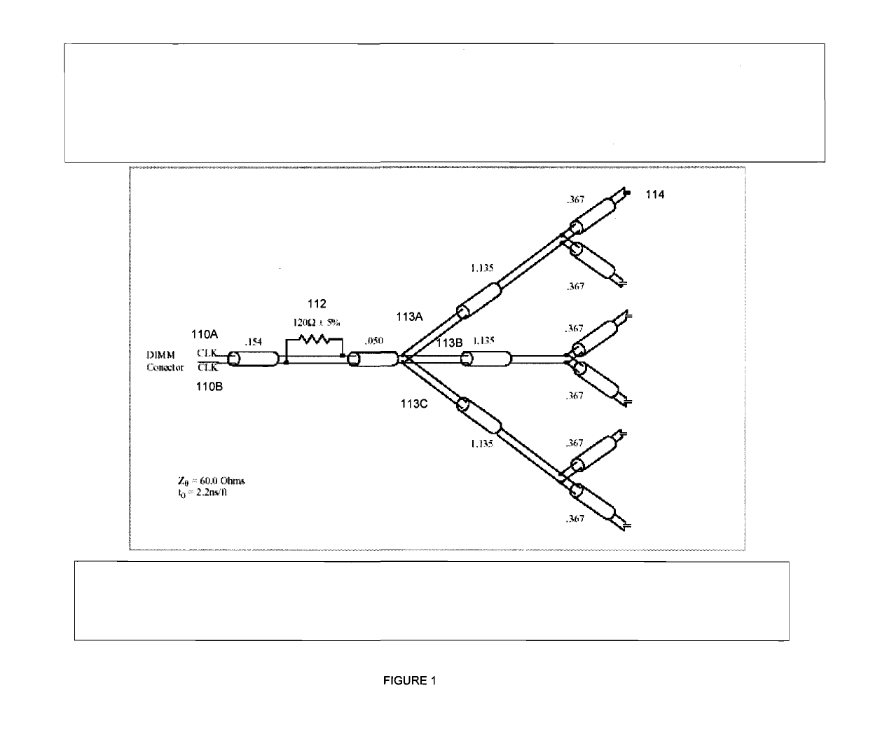

As noted above, FIG. 1 illustrates a prior art clock distribution network for one clock input where each clock input to the memory module can drive up to 6 memory device clock inputs. Each memory device is driven by one of the six possible clock distribution network outputs.

One disadvantage of present clock distribution methods is the 60-ohm transmission lines required for matched termination and the input capacitance of the of the memory devices. At low-speed operation, the rise and fall times do not significantly impact timing margin. For high-speed operation (at approximately DDR400 and up), clock signal rise and fall times represent a significant portion of the clock period and can contribute to timing and timing margin problems. The system illustrated in FIG. 1 is not well suited for high-speed operation or any operation where rise and fall times may compromise performance.

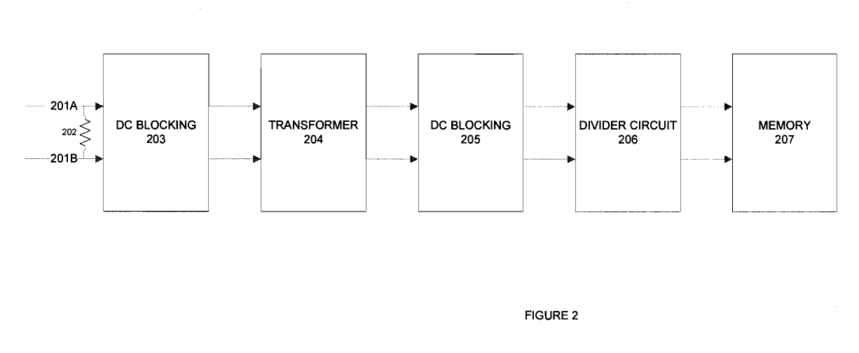

FIG. 2 is a block diagram of one embodiment of the invention. Differential clock signals 201A and 201B are coupled via resistor 202. The clock signals are provided to DC blocker 203. The output of DC blocker 203 is provided via transformer 204 to DC blocker 205. The output of DC blocker 205 is provided through divider circuit 206 to memory unit 207.

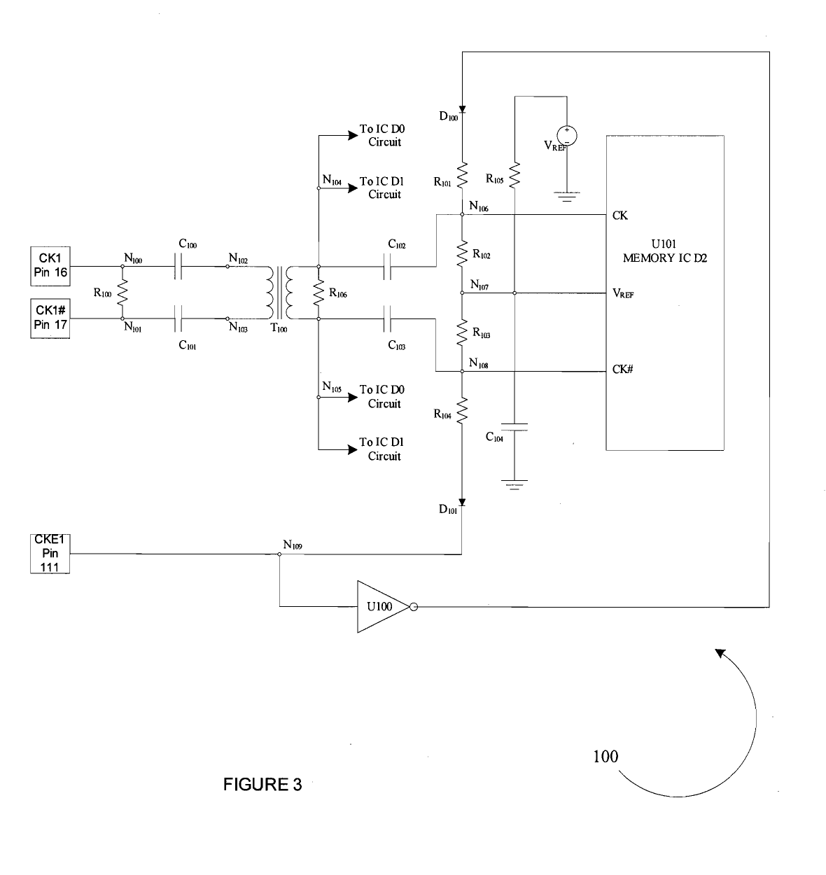

FIG. 3 is a circuit diagram of an embodiment of the invention of FIG. 2 for one clock input to a 184-pin DDR DIMM. The differential clock signal (CK1-CK1#) input to the DIMM is on pins 16 and 17 respectively. Input pin 16 is coupled to resistor R100 and capacitor C100 at node N100. Input pin 17 is coupled to resistor R100 and capacitor C100 at node N101. The value of resistor R100 is nominally 120-ohms and terminates the input transmission line from the motherboard as in the present art. The termination resistor may be located at various points along the clock distribution circuit including on the secondary of transformer T100.

Capacitor C100 couples node N100 to transformer T100 at node N102. Capacitor C101 couples node N101 to transformer T100 at node N103. Transformer T100 is a step down device with a turns-ratio that typically ranges from approximately 1.2:1 to nearly 4:1. The step down reduces capacitive loading on the motherboard and allows the clock distribution on the DIMM to be made using lower impedance transmission lines such as 30-ohms with a \sqrt{2}:1 ratio. As a result of the lower characteristic impedance, clock rise and fall times are significantly improved (by a factor of nearly 2 for the 30-ohm line example). The faster rise and fall times with associated decrease in timing variability can contribute to significantly increased timing margin.

The secondary winding of transformer T100 is coupled to nodes N104 and N1105. Resistor R106 couples node N104 to node N105. Capacitor C102 couples node N104 to the CK input of memory device U101 at node N106. Capacitor C103 couples node N105 to the CK# input of memory device U101 at node N107.

Capacitors C100, C101, C102 and C103 are DC blocking capacitors used to prevent DC saturation of both the primary and secondary transformer windings. Resistor R106 assists transformer reset and will typically be located across the secondary winding of the transformer for faster reset than would be realized if located across the primary winding. For high-speed DIMMs, it is common to need to invert clock phasing to the memory device input to meet required setup and hold timing requirements. This can be readily accomplished by swapping the CK and CK# connection to the memory device in the circuit board layout.

Resistor R102 couples node N106 to the VREF input to memory device U101 at node N107. Resistor R103 couples node N108 to the VREF input to memory device U101 at node N107. Resistors R102 and R103 provide a 1:1 ratio divider circuit. The divider circuit and the AC coupling of the clock typically results in a more symmetric spread of the differential clock circuit about VREF than achieved using the present art. Resistor R105 couples reference voltage VREF from the VREF source (typically pin 1 of the DIMM input) to the VREF input of U101 at node N107. Bypass capacitor C104 couples node N107 to ground (VSSQ for U101). Together, resistor R105 and capacitor C104 comprise a low pass filter for VREF.

During the period when the clock is not functional, there should be a positive DC offset between respective CK and CK# input to the memory devices. Using the present art and its characteristic DC clock coupling, the motherboard generates the necessary offset. Using the invention with AC clock coupling and no AC clock present, resistors R102 and R103 will pull both the CK and CK# inputs to the memory device together at a DC voltage of VREF and no DC offset between them. The necessary DC offset between CK and CK# is provided by the circuitry composed of inverter U100, resistors R101 and R104, and diodes D100 and D101. The diodes are small junction devices rather than Schottky devices.

When the clock is not present, the clock enable signal CKE (DIMM input pin 111) is low (near ground) and the output of inverter U100 is high. Current flows from the output of U100 through diode D100, resistors R101, R102, R103, and R104, diode D101 to CKE DIMM input pin. The resulting voltage drop across resistors R102 and R103 produce the necessary offset for CK and CK#. The offset is functionally DC since there is no predictable time when the clock will be again turned-on. When the clock is present, CKE will be high and the output of inverter U100 will be low. Diodes D100 and D101 will be reversed bias, functionally and effectively removing the clock offset bias circuitry from the clock interface. Only one offset bias circuit is typically required for all of the memory devices on most memory module applications.

FIG. 3 shows implementation of the invention for a single memory device. Distribution of the differential clock signals to additional memory devices (such as to ICs D0 and D1) requires duplication of the circuitry on the secondary of transformer T100 with the exception of resistor R106 and previously described offset bias circuit. Input signals to the duplicate circuitry are taken form nodes N104 and N105 for CK and CK# respectively. The embodiment has separate DC blocking capacitors for each memory device clock input located in close proximity to transformer T100 to minimize DC current interaction among the memory device clock circuits. The locations for controlled impedance clock distribution lines are those between the DC blocking capacitors and nodes N106 and N108 and their respective equivalent nodes on each additional memory device.

Thus, a transformer coupled clock interface circuit for memory modules has been described.

What is claimed:

1. A circuit comprising:
first and second clock inputs;
a transformer coupled to said first and second clock inputs;
the transformer having first and second outputs for coupling to an integrated circuit.

2. The circuit of claim 1 further including a first DC filter disposed between the clock inputs and the transformer.

3. The circuit of claim 2 further including a second DC filter disposed between the outputs of the transformer and the integrated circuit.

4. The circuit of claim 3 further including a divider circuit disposed between the second DC filter and the integrated circuit.

5. The circuit of claim 4 wherein the first and second clock inputs are differential.

6. The circuit of claim 5 wherein the integrated circuit is a memory module.

7. The circuit of claim 6 wherein the transformer is such that lower characteristic impedance transmission lines may be used in the circuit.

8. The circuit of claim 7 wherein the circuit has improved margins for rise and fall time of the clock inputs.
